(19) United States
(12) Patent Application Publication
(10) Pub. No.: US 2025/0379033 A1
(43) Pub. Date: Dec. 11, 2025

(54) APPARATUS AND METHOD FOR MODULATING SPATIAL DISTRIBUTION OF PLASMA AND ION ENERGY USING FREQUENCY-DEPENDENT TRANSMISSION LINE

(71) Applicant: Lam Research Corporation, Fremont, CA (US)

(72) Inventors: David French, Fort Myers, FL (US); Karl Frederick Leeser, West Linn, OR (US)

(73) Assignee: Lam Research Corporation, Fremont, CA (US)

(21) Appl. No.: 18/877,069

(22) PCT Filed: Jul. 7, 2023
(86) PCT No.: PCT/US2023/027094

§ 371 Date: Dec. 19, 2024

Related U.S. Application Data
(60) Provisional application No. 63/368,138, filed on Jul. 11, 2022.

(51) Int. Cl. H01J 37/32

(52) U.S. Cl. CPC H01J 37/32174; H01J 37/321

(57) ABSTRACT

A system includes a chamber comprising first and second regions. The chamber is configured to produce and contain a plasma in the second region. The system includes a transmission line positioned in the first region. The transmission line includes a plurality of sections, wherein an individual section of the plurality of sections includes one or more L-C filters which have respective cut-off frequencies. The transmission line includes a transmission line input. A signal source electrically is coupled to the transmission line input to feed an input signal to the transmission line input. The one or more L-C filters pass low frequency components of the input signal but localize high frequency components of the input signal to selected sections of the transmission line.

### CLAIM FOR PRIORITY

This application claims priority to U.S. Provisional Patent Application No. 63/368,138, filed on Jul. 11, 2022, titled “APPARATUS AND METHOD FOR MODULATING SPATIAL DISTRIBUTION OF PLASMA AND ION ENERGY USING FREQUENCY-DEPENDENT TRANSMISSION LINE,” and which is incorporated by reference in entirety.

### BACKGROUND

Plasma deposition is a process utilized to deposit thin films on a substrate using a plasma source. The plasma may be created by a radio frequency (RF) current or a direct current (DC) in a plasma chamber. For semiconductor device fabrication, uniformity in thin film deposition across a substrate is highly desirable. Uniformity in deposition can lead to uniformity in devices fabricated that have substantially the same electrical performance. In a deposition process, uniformity across a substrate or cross wafer uniformity is controlled by many factors, such as spatial control of inductive electric field that drives and sustains the plasma, reaction rates, or design of gas distribution. The inductive electric fields control electrical potential within a plasma. Modulating spatial distribution and ion energy of the plasma can provide numerous advantages for deposition. The spatial distribution of ion energy and angular distribution can be controlled by changing parameters that affect bulk plasma properties, as well as by changing electrical parameters (e.g., voltage, frequency) of a signal that is driving the inductive electric field. Methods and systems for modulating the spatial distribution and ion energy of the plasma are being constantly developed.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

FIG. 1 illustrates an apparatus, in accordance with at least one example.

FIGS. 2-4 illustrate transmission lines, in accordance with at least one example.

FIG. 5 illustrates simulated frequency responses of L-C filters of a transmission line, in accordance with at least one example.

FIG. 6A illustrates a plot showing voltage produced in a transmission line; FIG. 6B is a plot showing a zoomed view of the voltage; and FIG. 6C illustrates a plot showing a low frequency signal and a high frequency signal applied to the transmission line, in accordance with at least one example.

FIG. 7 illustrates a flow diagram of a method, in accordance with at least one example.

FIG. 8 illustrates a processor system with machine-readable storage media having instructions that when executed cause the processor to modulate plasma, in accordance with at least one example.

### DETAILED DESCRIPTION

An apparatus and a method for modulating a spatial distribution and ion energy of plasma using a frequency-dependent transmission line is described, in accordance with at least one example. In the following description, numerous specific details are set forth, such as structural schemes to provide a thorough understanding of examples of the present disclosure. It will be apparent to one skilled in the art that examples of the present disclosure may be practiced without these specific details. In other instances, well-known features, such as radio frequency sources, are described in lesser detail to not unnecessarily obscure examples of the present disclosure. Furthermore, it is to be understood that the various examples shown in the Figures are illustrative representations and are not necessarily drawn to scale.

In some instances, in the following description, well-known methods and devices are shown in block diagram form, rather than in detail, to avoid obscuring the present disclosure. Reference throughout this specification to “an example” or “at least one example” or “one example” or “some examples” means that a particular feature, structure, function, or characteristic described in connection with the examples is included in at least one example of the disclosure. Thus, the appearances of the phrase “in an example” or “in one example” or “some examples” in various places throughout this specification are not necessarily referring to the same example of the disclosure. Furthermore, the particular features, structures, functions, or characteristics may be combined in any suitable manner in one or more examples. For example, a first example may be combined with a second example anywhere the particular features, structures, functions, or characteristics associated with the two examples are not mutually exclusive.

Here, “coupled” and “connected,” along with their derivatives, may be used herein to describe functional or structural relationships between components. These terms are not intended as synonyms for each other. Rather, in particular examples, “connected” may be used to indicate that two or more elements are in direct physical, optical, or electrical contact with each other. “Coupled” may be used to indicated that two or more elements are in either direct or indirect (with other intervening elements between them) physical, electrical or in magnetic contact with each other, and/or that the two or more elements co-operate or interact with each other (e.g., as in a cause an effect relationship).

Here, “over,” “under,” “between,” and “on” as used herein refer to a relative position of one component or material with respect to other components or materials where such physical relationships are noteworthy. Unless these terms are modified with “direct” or “directly,” one or more intervening components or materials may be present. Similar distinctions are to be made in the context of component assemblies. As used throughout this description, and in the claims, a list of items joined by the term “at least one of” or “one or more of” can mean any combination of the listed terms.

Here, “adjacent” may generally refer to a position of a thing being next to (e.g., immediately next to or close to with one or more things between them) or adjoining another thing (e.g., abutting it).

Unless otherwise specified in the explicit context of their use, the terms “substantially equal,” “about equal” and “approximately equal” mean that there is no more than incidental variation between two things so described. In the art, such variation is typically no more than +/−10% of the referred value.

Here, “coil” may generally refer to a form of an inductor that comprises a wire or other conductor that is wound into one or more turns, generally circular. In at least one example, a coil may be in the form of a flat spiral, or a solenoid adjacent to a flat- or dome- or tapered dielectric window. In at least one example, geometric factors such as number of turns, spacing between turns, the diameter and length of the coil, as well as other dimensions such wire thickness, and distance of the wire to plasma may also influence the inductance of a coil.

Here, “transmission line” may generally refer to a plurality of conductive elements or segments electrically coupled. In at least one example, transmission lines may be built using discrete elements (e.g., inductors, capacitors). In at least one example, an individual wire of a transmission line may be represented by an inductance L shunted by a distributed capacitance C per unit length, where the distributed capacitance is proportional to the dielectric constant of the dielectric material between the conductors.

Here, “terminal” may generally refer to the end of a conductor or electrical component, such as a wire, which may be a point of connection for other conductors or electrical components. In the context of a coil, in at least one example, a terminal is the end of a winding. Referring to coil segments, in at least one example, a coil segment may comprise a terminal at the beginning and the end of a coil segment conductor.

Here, “inductor” may generally refer to passive electrical device that stores magnetic energy from an electrical current flowing through it. In at least one example, an inductor may comprise a conductor (e.g., a metal wire) that may couple an electrically generated magnetic field into another conductor that is nearby, inducing a voltage and current in the second conductor. In at least one example, magnetic field may be generated by currents flowing within the first conductor according to Faraday's law of induction. Conductors have the property of inductance, which is a function of the magnitude of the current flowing within the conductor and the shape or geometry of the conductor. While any conductor may be an inductor, some shapes produce a stronger inductance than others. In at least one example, a straight wire may have a small inductance that is dependent on its diameter and length. In at least one example, a straight wire may be wound into a coil to multiply the inductance by the number of windings per unit length due to mutual additive coupling of magnetic fields between each winding, reinforcing the overall magnetic field. In at least one example, magnetic fields from each winding couple, produce a multiplication of the magnetic field produced by the straight wire according to Ampere's law. In at least one example, a coil may be a planar coil, or a helical coil, such as a solenoid or tapered helix.

Here, “capacitor” may generally refer to a passive electrical device that stores electrical charge and electrical energy in the form of an electric field. In at least one example, a capacitor generally has at least two conductive plates in proximity to one another, separated by a dielectric material. In at least one example, dielectric material may be air (or other gas) or vacuum. In at least one example, dielectric may generally be a solid or liquid material, such as a polymer, a ceramic, or a semi-liquid electrolyte. In at least one example, opposite electrical charges may accumulate on the adjacent plates, forming an electric field extending from plate to plate through the dielectric. The electric field can store electrical energy.

Here, “plasma” may generally refer to a gaseous formation comprising charged particles, such as positively or negatively charged atomic or molecular ions and electrons. Plasmas are considered the fourth state of matter.

Here, “spatial distribution of a plasma” may generally refer to an arrangement or pattern of ions of the plasma. In at least one example, arrangement or pattern of the ions indicates distance between the ions or density of the ions in the plasma.

Here, “modulate” may generally refer to vary or to adjust, and the term “modulate plasma” may generally refer to vary a spatial distribution and ion energy of the plasma.

Here, “inductively coupled plasma” (ICP) may generally refer to a plasma that is generated by time-varying magnetic fields emanating from a primary inductor or plasma antenna, generally in the form of a coil, conducting a radio frequency (RF) current. In at least one example, a small concentration of ionized atoms or molecules and free electrons within a gas may be generated in a discharge. In at least one example, slightly ionized gas may be regarded as a secondary inductor coupled to the plasma antenna, which may be considered the primary inductor of a transformer where the plasma may be considered the secondary inductor of the transformer to which the primary inductor couples. In at least one example, gas may pass through an electromagnetic field produced by the adjacent ICP antenna, where the charges are accelerated by the time-varying electric fields associated with the time-varying magnetic fields (according to Faraday's law of induction and the Faraday-Maxwell equation). In at least one example, accelerated electrons may collide with neutral atoms or molecules to produce more ions and secondary electrons, building up the plasma density of charged particles. In at least one example, magnitude of particle acceleration and hence collision velocity is proportional to the strength of the electric fields, which in turn are proportional to the magnetic field strength. In at least one example, magnetic field strength is proportional to the magnitude of current flowing within the ICP antenna.

Here, “tuned portion” may generally refer to a portion of an ICP antenna. In at least one example, tuned portion may be a region or section specifically tuned or configured to provide more, less, or different power than another region or section to alter spatial uniformity of a plasma.

Here, “untuned portion” may generally refer to a portion of an ICP antenna. In at least one example, an untuned portion may be a region or section that is not specifically tuned or configured to provide more, less, or different power than another region to alter spatial uniformity. In at least one example, untuned portion may also be generally referred to as background RF drive signal region or section configured to sustain a plasma.

Here, “tank circuit” may generally refer to a parallel combination of an inductor and a capacitor. In at least one example, a tank circuit has a characteristic resonant frequency f0 that is determined by the values of inductance L and capacitance C, where f0=1/[2p√LC]. In at least one example, a tank circuit has a resonance curve that is a plot of circuit impedance as a function of frequency. The curve is non-monotonic in that it has a peak at the resonant frequency. In at least one example, sharpness and bandwidth of the resonance curve is determined by the quality factor Q of the circuit. Q may be defined as the ratio of energy stored in the electric field and magnetic field of the capacitor and inductor, respectively, to the energy dissipated as heat by resistive parts of the circuit. In at least one example, resistance may mostly be in the inductor (e.g., as copper loss, skin effect), as it may comprise a long piece of thin wire wound into a coil. In at least one example, smaller the resistance of the coil, the larger the Q. In at least one example, Q may be lowered by insertion of a discrete resistor in series with the inductor in the tank circuit. In at least one example, resonance curve may be broadened by a low circuit Q (e.g., Q<10), and sharpened by a high circuit Q (e.g., Q>10). In at least one example, tank circuits exhibit very large circulating currents at or near resonance. In at least one example, circulating current may be the product of the line, or feed current, multiplied by the Q. In at least one example, very large voltages may also appear across the capacitor and inductor because of the large circulating current. At the same time, in at least one example, impedance of the tank circuit increases dramatically at or near resonance and becomes purely resistive at f0. In at least one example, resonant tank circuits can have a very high effective resistance that severely reduces conduction of the RF current at f0. Here, “tank” circuit is derived from the circuit's ability to store electrical energy. In at least one example, tank circuits are used as frequency-determining components of oscillator circuits and tuned coupling circuits, such as found in tuned RF amplifier stages.

Here, “dielectric material” may generally refer to a non-electrically conductive material, such as a polymer, a ceramic, glass, wood, etc.

Here, “radio frequency” may generally refer to electromagnetic radiation that oscillates at frequencies in a spectrum that is substantially inclusive of frequencies between 10 kilohertz (kHz) and 1 terahertz (THz, or 1015 Hz). In at least one example, the upper limit of radio frequency spectrum may extend only to several hundred gigahertz (GHz). Radio frequency as a term may be abbreviated to “RF”.

Here, “RF signal source” or “signal source” may generally refer to an electronic device that can generate electrical signals at radio frequency. In at least one example, RF signal source is capable of outputting significant RF current (e.g., 1 ampere rms or greater) at significant voltages. In at least one example, RF signal sources for ICP antennas generally are capable of outputting up to hundreds of amperes at up to several hundred volts, generating significant electrical power.

Here, “process tool” may generally refer to a piece of equipment employed in semiconductor fabrication, also referred to as a “semiconductor process tool” for semiconductor processing, In at least one example, process tool may generally comprise a vacuum chamber in which processes such as substrate plasma etching or plasma-enhanced material deposition are carried out. In at least one example, other non-plasma related processes may also be performed in a process tool.

Here, “L-C filter” may generally refer to a filter which includes an inductor L and a capacitor C. In at least one example, inductance and capacitance values of the inductor L and the capacitor C can be selected to pass specific frequency bands of an electrical signal while attenuating or filtering other frequency bands.

Here, “chuck” may generally refer to a stage or platform on which a substrate (e.g., a wafer) may be attached.

Here, “electrostatic chuck” may generally refer to a platform which may include an electrode plate and an insulator disposed on the electrode plate.

Here, “substrate” may generally refer to a wafer comprising a semiconductor (e.g., silicon) or an insulator (e.g., aluminum nitride, silicon carbide, silicon nitride, aluminum oxide, float glass, borosilicate glass, etc.). A wafer may be a slice of monocrystalline semiconductor or insulator. In at least one example, a wafer may also comprise a polycrystalline or an amorphous (glassy) material. In at least one example, wafer may have a diameter generally ranging between 100 mm to 500 mm, and a thickness generally ranging between 100 microns and 1 mm.

Here, “process chamber” may generally refer to a vacuum chamber of a process tool into which a substrate may be introduced for processing. In at least one example, process chamber may include a chuck for holding the substrate. An example of a process chamber is a plasma etch chamber.

Here, “chamber” or “plasma chamber” may generally refer to a process chamber in which plasma may be produced for processing.

Here, “utility chamber” may generally refer to a chamber or enclosure on a process tool where electronics or other sensitive equipment may be housed and isolated from the process chamber. In at least one example, an ICP antenna may be housed in the utility chamber, isolated from the generally harsh environment of the process chamber. In at least one example, utility chamber may be held under vacuum or at atmospheric pressure.

Here, “first region” may generally refer to a region in a chamber where a transmission line is positioned.

Here, “second region” may generally refer to a region in a chamber where gas or plasma may be contained.

Here, “separation window” or “dielectric window” may generally refer to a window which partitions a chamber into a first region and a second region. In at least one example, separation window or dielectric window may be constructed with a non-electrically conductive material (e.g., dielectric), such as a polymer, a ceramic, glass, wood, etc.

Here, “spatial control” may generally refer to positional control of a process. In at least one example, spatial control of a plasma etch or deposition by providing spatially resolved coupling of an ICP antenna to a plasma.

Here, “input signal” may generally refer to a signal of a desired frequency provided by a signal source.

Here, “cut-off frequency” may generally refer to a frequency below which all frequencies are allowed to pass through a filter. In at least one example, a filter may be tuned to have a cut-off frequency of around 200 MHz in which case frequencies below 200 MHZ are allowed to pass through the filter but frequencies above 200 MHz are blocked.

Here, “coupled” may generally refer to direct attachment of one electronic component to another. In at least one example, electric or magnetic field may couple one component to another, where the field is controlled by one component to influence the other in some manner.

Here, “low frequency signals” or “low frequency components” may generally refer to signals having a frequency range between 0 Hz and 0.5 kHz.

Here, “high frequency signals” or “high frequency components” may generally refer to signals having a frequency range above 0.5 MHz.

Here, “magnetic field” may generally refer to lines of magnetic flux direction and intensity emanating from a magnetized material or current-carrying material.

Here, “plasma-enhanced process” may generally refer to a semiconductor process, for example, where a plasma is employed to aid the process in some way. In at least one example, a plasma enhanced process is enhanced over a similar or same process without a plasma. An example is reactive ion etching and plasma-enhanced chemical vapor deposition or plasma enhanced atomic layer deposition.

Here, “reactive species” may generally refer to ions or neutral radicals formed in a plasma.

Here, “section” or “selected section” may generally refer to a part or a portion of a transmission line which includes a number of segments.

Here, “localize” may generally refer to allowing selected frequencies (e.g., around 10 MHz or higher) to propagate within selected number of segments or sections of a transmission line.

Here, “ion” may generally refer to a charged atom or molecule. In the context of the disclosure, an ion may be a gaseous atom or molecule that loses or gains an electron in a plasma.

Here, “machine-readable storage medium” may generally refer to a memory that stores binary code or data that is readable by a processor. In at least one example, machine-readable storage medium may be a non-volatile solid state storage medium, a magnetic hard drive, an optical disc, etc.

Here, “machine-readable instructions” may generally refer to binary code stored on a machine-readable storage medium. When executed, in at least one example, binary code or instructions may cause a processor to perform certain functions.

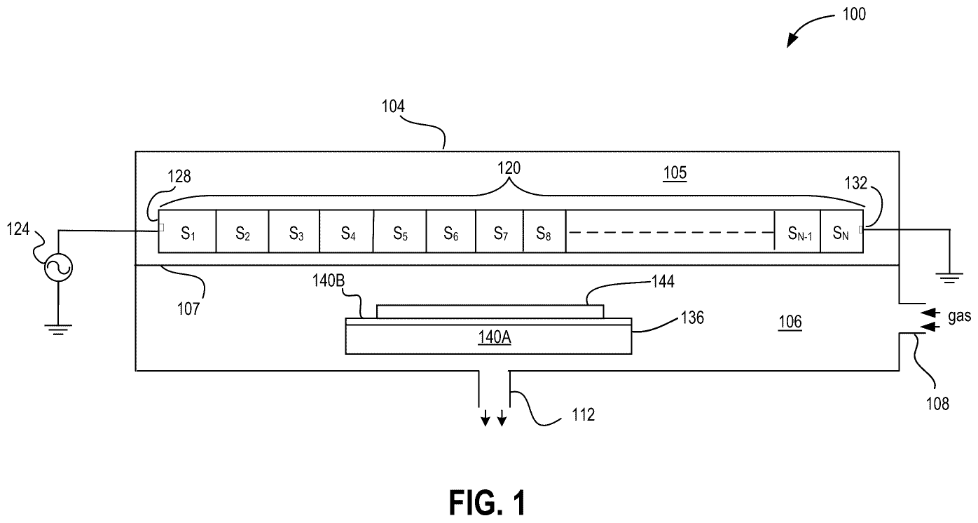

FIG. 1 illustrates system 100 in accordance with at least one example. In at least one example, system 100 includes a chamber 104, a first region 105, a second region 106, a separation window 107, an intake valve 108, an exhaust valve 112, a transmission line 120, a signal source 124, an input terminal 128, a termination node 132, an electrostatic chuck 136, an electrode plate 140A, an insulator 140B, and a wafer 144.

In at least one example, chamber 104 is configured to generate and contain plasma. In at least one example, chamber 104 may be partitioned into first region 105 and second region 106 by separation window 107. In at least one example, separation window 107 may be constructed with a non-electrically conductive material (e.g., dielectric), such as a polymer, a ceramic, glass, wood, etc. First region 105 is also referred to as an antenna region or a transmission line region. Second region 106 is also referred to as a vacuum region or a plasma region (e.g., region containing plasma).

In at least one example, chamber 104 may include intake valve 108 through which gas is pumped into the chamber and may include exhaust valve 112 for removal of the gas. In at least one example, gas is generally contained in second region 106. Although plasma chamber 104 is shown as having a rectangular shape, in at least one example, plasma chamber 104 can be built having other suitable shapes such as, but not limited to, a dome shape.

In at least one example, system 100 includes transmission line 120 in first region 105. In at least one example, transmission line 120 comprises a plurality of sections S₁-S_{N} (also referred to as transmission line segments S₁-S_{N}). In at least one example, individual sections S₁-S_{N} may each include one or more L-C filters (not shown in FIG. 1) which are described in detail below. In at least one example, signal source 124 is electrically connected to transmission line 120 at input terminal 128. Signal source 124 feeds a signal of a desired frequency to transmission line 120. In at least one example, transmission line 120 has termination node 132 which is coupled to a common potential (hereinafter referred to as “ground”). In at least one example, termination node 132 may be capacitively coupled to ground.

In at least one example, system 100 includes electrostatic chuck 136 in second region 106. Electrostatic chuck 136 may include electrode plate 140A and insulator 140B disposed on electrode plate 140A. In at least one example, insulator 140B may include dielectric materials including ceramics such as alumina (Al₂O₃), silicon dioxide (SiO₂), silicon nitride (Si₃N₄), and/or sapphire. In at least one example, a wafer or semiconductor substrate 144 is placed on electrostatic chuck 136.

In operation, in at least one example, system 100 controls plasma-assisted deposition, cleaning or etching on substrate 144 by spatially modulating ion energy distributions within a plasma created within plasma chamber 104. In at least one example, by changing electrical parameters such as the frequency and voltage of the applied signal that is fed into transmission line 120, system 100 also controls the spatial distribution and the ion energy of the plasma. In at least one example, system 100 is operable to spatially control plasma processes such as PECVD or PEALD, as well as plasma cleaning and ion etch processes such as reactive ion etching, on substrate 144.

Although transmission line 120 is illustrated as having a linear structure, in at least one example, transmission line 120 can have other suitable shapes. In at least one example, transmission line 120 can be wound into a coil such as a pancake-shaped coil.

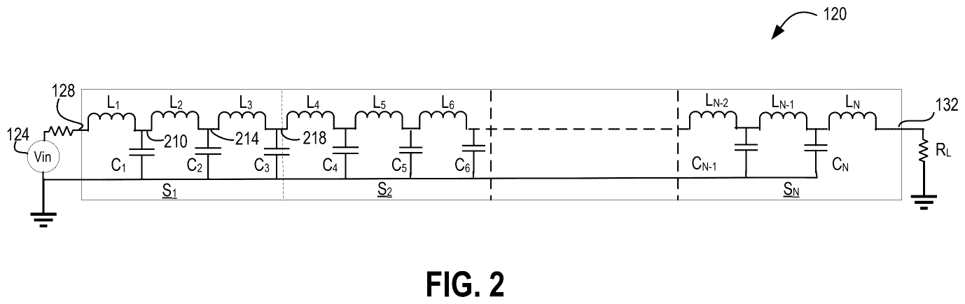

FIG. 2 illustrates transmission line 120 in accordance with at least one example. In at least one example, transmission line 120 includes a plurality of sections S₁-S_{N} (i.e., transmission line segments), each having at least one L-C filter. In at least one example, section S₁ includes three L-C filters: a first L-C filter formed by an inductor L₁ and a capacitor C₁; a second L-C filter formed by an inductor L₂ and a capacitor C2; and a third L-C filter formed by an inductor L₃ and a capacitor C3. In at least one example, sections S₂-S_{N} each include three L-C filters. In at least one example, L-C filters are configured as low-pass filters which are coupled together to form an L-C ladder network. As illustrated in FIG. 2, L₁ is coupled to L₂ at node 210, and C₁ is coupled between node 210 and ground. L₂ is coupled to L₃ at node 214, and C₂ is coupled between node 214 and ground. L₃ is coupled to L₄ at node 218, and C₃ is coupled between node 218 and ground. In at least one example, other inductors L₅-L_{N} and capacitors C₅-C_{N} are coupled similarly. In at least one example, signal source 124 is coupled to L1 at input terminal 128 to feed a signal of desired frequency and voltage to transmission line 120. In at least one example, a resistor R can be coupled in series between signal source 124 and L1, thus allowing precise control of the current fed into transmission line 120. In at least one example, a series capacitor (not shown in FIG. 1) may be coupled between termination node 132 and ground. In at least one example, a capacitor may capacitively couple termination node 132 to ground. In at least one example, termination point 132 can be directly coupled to.

By selecting inductance values of inductors L₁-L_{N} and capacitance values of capacitors C₁-C_{N}, in at least one example, L-C filters can be configured as low-pass filters having respective cut-off frequencies. In at least one example, capacitors C₁-C_{N} may have same capacitance, but inductors L₁-L_{N} may have different inductances. Because the cut-off frequency of an L-C filter is given by the following relationship: f_{cut-off}=1/(2π\sqrt{LC}), in at least one example, cut-off frequency of transmission line 120 varies with the position on transmission line 120.

In at least one example, inductance values are chosen so that the inductance of an inductor in transmission line 120 increases as it is positioned farther down transmission line 120. In at least one example, input signals fed into transmission line 120 pass through inductors having higher and higher inductances. In at least one example, the following inductance and capacitance values are selected: L₁=49 nH, C₁=2 uF; L₂=60 nH, C₂=2 uF; L₃=72 nH, C₃=2 uF; L₄=87 nH, C₄=2 uF; and L₅=106 nH, C₅=2 uF. In at least one example, other inductances of L₆-L_{N} can be chosen so the inductance of an inductor increases as it is positioned farther down transmission line 120. In at least one example, capacitances of C₁-C_{N} may not be the same.

Because inductance of an inductor increases, as it is positioned farther down transmission line 120, in at least one example, the cut-off frequency of an L-C filter decreases as it is positioned farther down transmission line. In at least one example, transmission line 120 includes a plurality of L-C filters which have decreasing cut-off frequencies along the length of transmission line 120. As a result, in at least one example, input signals propagating through sections of transmission line 120 are filtered by a plurality of filters having decreasing cut-off frequencies. The effect of this is that lower frequencies (also referred to as low frequency components) can pass through transmission line 120 and thus can be applied uniformly to transmission line 120 but higher frequencies (e.g., RF frequencies above 10 MHz) are filtered or attenuated (blocked) by the L-C filter sections and are thus localized within selected L-C filter sections. Thus, the low frequency components are passed by one or more L-C filters to uniformly apply the low frequency components to the transmission line. In at least one example, the cut-off frequencies of the L-C filters can be chosen to allow a range of low frequency signals (e.g., 0 Hz-0.5 kHz) to be applied uniformly to transmission line 120 while localizing high frequency signals (e.g., >0.5 MHZ).

In at least one example, the sixth L-C filter (L₆, C₆) has a cut-off frequency of approximately 1 MHZ, the ninth L-C filter (L₆, C₆) has a cut-off frequency of approximately 0.8 MHz, and the eleventh L-C filter (L₁₁, C₁₁) has a cut-off frequency of approximately 0.6 MHz. The effect of this is that a 1 MHz signal propagates up to the sixth L-C filter (L₆, C₆), a 0.8 MHz signal propagates up to the ninth L-C filter (L₆, C₉), and a 0.6 MHz signal propagates up to the eleventh L-C filter (L₁₁, C₁₁). In at least one example, the L-C filters can be designed to localize higher frequencies to selected sections of transmission line 120 while allowing lower frequencies (e.g., 0 Hz-0.5 kHz) to propagate through the entire length of transmission line 120.

In at least one example, transmission line 120 is a frequency-dependent structure which is used to control the spatial distribution and ion energy of the plasma by varying the frequency and voltage of the input signals fed into transmission line. By selecting the frequency of input signals, in at least one example, voltage generated due to high frequency signals can be localized at one more sections of transmission line 120. In at least one example, by changing (e.g., varying or adjusting) the frequency of the input signal, localized voltage generated due to the high frequency signals (e.g., high frequency components) can be switched from one or more sections to other one or more sections. In at least one example, selected sections in which high frequency components are localized are switched by change in a frequency of the input signal fed to transmission line 120. In at least one example, by varying the amplitude of the high frequency signals, localized voltage at selected sections of transmission line 120 can be increased or decreased. In at least one example, by selecting the frequency of the input signals, only selected sections of transmission line 120 can be allowed to radiate (strong electromagnetic (EM) field coupling to the plasma), and by varying the amplitude of the signals, the localized electromagnetic radiation can be increased or decreased.

In at least one example, the frequency-dependent property of individual transmission line segments may be exploited to control the spatial distribution and ion energy of an inductively coupled plasma in plasma chamber 104. As the efficiency of coupling of inductively coupled plasmas to EM fields may be frequency dependent, in at least one example, plasma characteristics may be spatially controlled. In at least one example, by localizing voltage and current having selected frequencies within selected sections of transmission line, spatial distribution and ion energy of plasma in areas adjacent to those sections are modulated (e.g., increased or decreased) relative to portions of the plasma coupled to transmission line segments, permitting lower frequency RF currents to flow. In at least one example, by varying the amplitude (e.g., voltage) of the input signals, the localized current and voltage levels (and the associated EM field) can be raised or lowered, thus providing a means to modulate or vary (e.g., increase or decrease) the spatial distribution and ion energy of the plasma in those areas. In at least one example, the spatial distribution and ion energy of the plasma in second region 106 is modulated in areas adjacent to the selected sections of transmission line 120. In at least one example, in selected sections of transmission line 120, the spatial distribution of the plasma is modulated by variation of a voltage of the input signal.

If a high frequency signal is superimposed on a low frequency signal and fed into transmission line 120, the low frequency signal may be applied uniformly along transmission line 120. In at least one example, lower frequency may be below all of the cut-off frequencies of the plurality of sections of transmission line 120, permitting propagation along the totality transmission line 120 and into a terminating load. In at least one example, the high frequency signal may be localized within a limited portion of transmission line 120 comprising selected sections of transmission line 120. In at least one example, the frequency of the higher frequency signal may be above the cut-off frequency of selected transmission line sections. In at least one example, higher frequency signal may thus be confined to a portion of transmission line 120 having a cut-off frequency higher than that of the higher frequency signal. In at least one example, effect of this is that selected sections of transmission line 120 will have a higher voltage level than other sections, and thus the spatial distribution and ion energy of the plasma in areas adjacent to the selected sections can be modulated.

In at least one example, a 1 MHz RF signal can be superimposed on a DC voltage and the combined signal may be applied to transmission line 120. In at least one example, DC voltage may be present uniformly along transmission line 120. Since the 1 MHz signal may propagate up to section S₂, the voltage generated due to the 1 MHz signal may be localized in sections S₁ and S₂. The effect of this is that a higher voltage level may be present at sections S₁ and S₂ and a lower voltage level may be present at sections S₃-S_{N}.

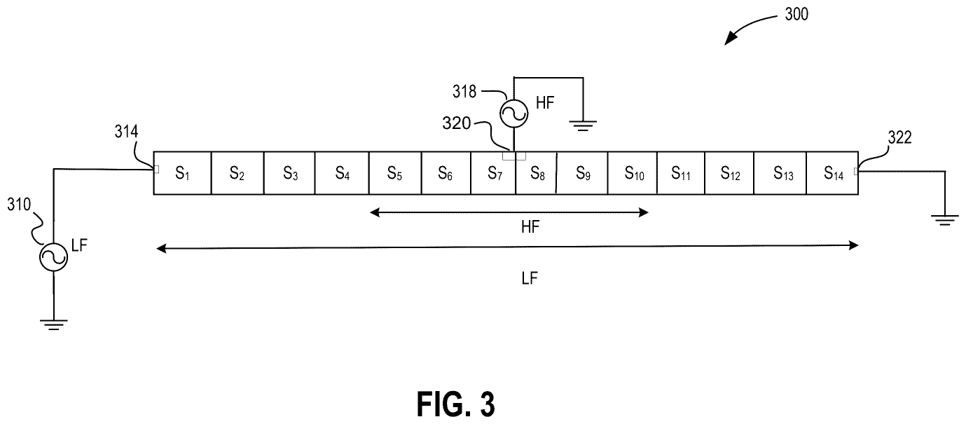

In at least one example, a plurality of signal sources can feed signals having different frequencies to a transmission line. FIG. 3 illustrates a transmission line 300, in accordance with at least one example. In at least one example, transmission line 300 includes sections S₁-S₁₄, a first input 314, a second input 320, and a termination node 322. In at least one example, sections S₁-S₁₄ each include one or more L-C filters (not shown in FIG. 3). A low frequency signal source 310 feeds a low frequency signal at first input 314, and a high frequency signal source 318 feeds a high frequency signal at second input 320. In at least one example, transmission line 300 includes termination node 322 which is coupled to ground. In at least one example, low frequency signal is uniformly applied to transmission line 300. In at least one example, the high frequency signal is localized in sections S₅-S₁₀. If, for example, the high frequency signal is a 25 MHz signal, the cut-off frequencies of S₅ and S₁₀ can be set to 20 MHz to localize the high frequency signal in sections S₅-S₁₀.

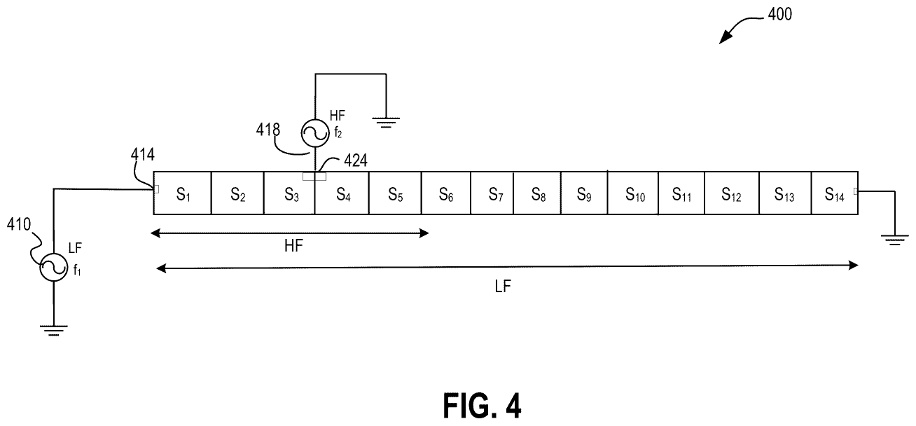

FIG. 4 illustrates a transmission line 400 in accordance with at least one example. In at least one example, transmission line 400 includes a first input 414 and a second input 424. In at least one example, a first signal source 410 feeds a low frequency signal having a frequency f1 (e.g., 400 kHz signal) to first input 414. Since the low frequency signal is uniformly applied to transmission line, in at least one example, the low frequency signal (e.g., 400 kHz signal) can be used to drive the main plasma in a plasma chamber (not shown in FIG. 4). In at least one example, signal source 418 feeds a high frequency signal having a frequency f2 (e.g., 25 MHz signal) at second input 424. In at least one example, high frequency signal (e.g., 25 MHz signal) is localized in sections S₁-S₅. In at least one example, low frequency signal (e.g., 400 kHz signal) can be used for low power operation, and the high frequency signal (e.g., 25 MHz signal) can be used to locally excite sections S₁-S₅ of transmission line 400 and/or used for ignition of the system. In at least one example, amplitude of the high frequency signal (e.g., 25 MHz signal) can be adjusted to modulate the spatial distribution of the plasma.

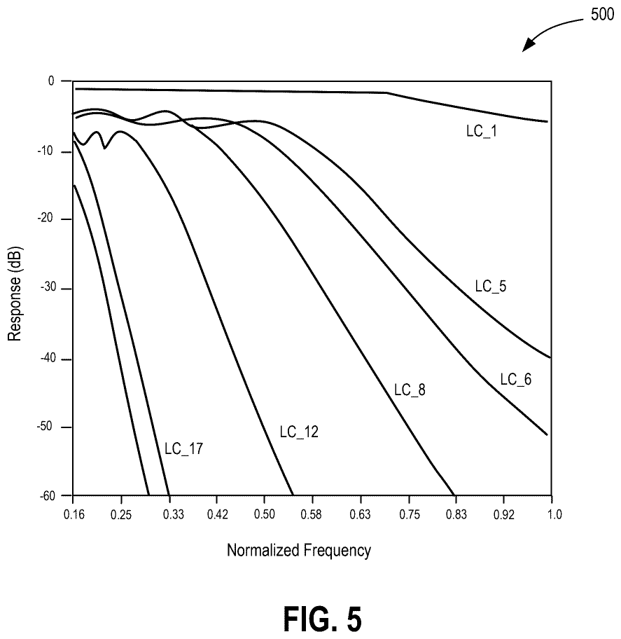

FIG. 5 illustrates an example plot 500 showing a plurality of curves. Individual curves in FIG. 5 represent frequency responses of successive sections within a transmission line (e.g., transmission line 120). In at least one example, the first transmission line segment, comprising a first LC filter network (e.g., indicated as LC_1), has a cut-off frequency at approximately 1 MHz signals (normalized at 1.0 on the x-axis in FIG. 5). In at least one example, signals having frequencies at or below 1 MHZ (normalized at 1.0 on the x-axis in FIG. 5) may pass with little to moderate attenuation. In at least one example, fifth transmission line segment comprising a fifth filter network (indicated as LC_5) has a cut-off frequency at approximately 600 kHz (normalized at 0.5 on the x-axis in FIG. 5) In at least one example, signals having frequencies above 600 kHz (normalized at 0.5 on the x-axis in FIG. 5) may be attenuated, while signals having frequencies below 600 kHz may pass into succeeding sections 6-17. In at least one example, seventeenth transmission line segment comprises a 17th LC filter network (e.g., indicated as LC_17) having a cut-off frequency at approximately 270 kHz. Thus, the lowest frequency signals may propagate along the entire length of the transmission line.

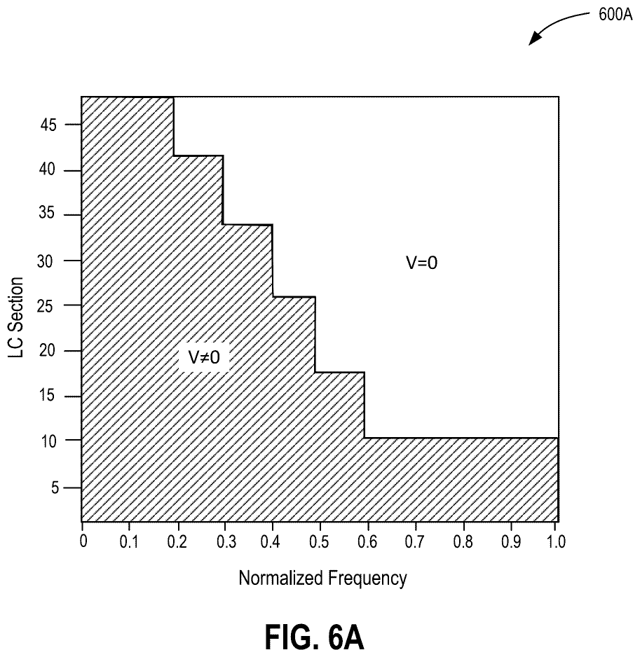

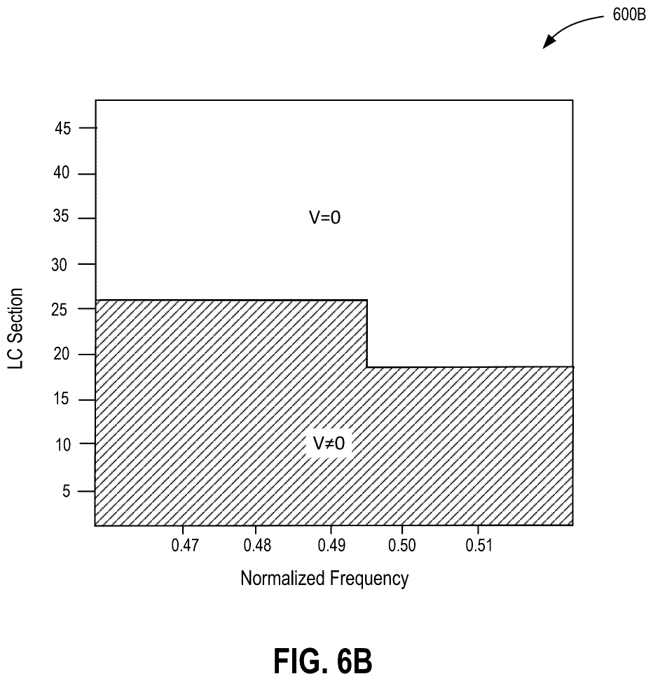

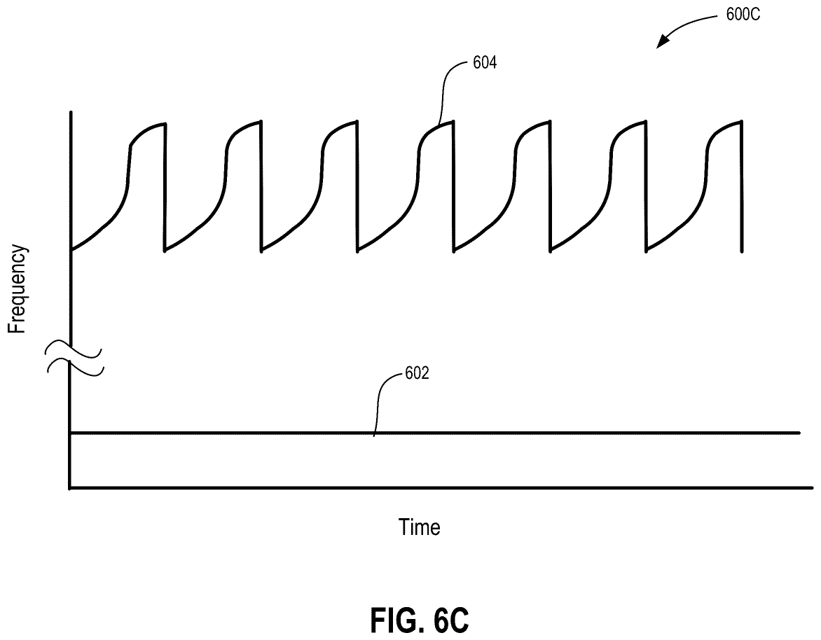

FIG. 6A illustrates an example plot 600A showing simulated localized voltage produced within successive sections of a transmission line built in accordance with examples of the disclosure. In FIG. 6A, the x-axis of plot 600A represents frequency (normalized at 1.0 on the x-axis in FIG. 6A), and the left y-axis represents sections of the transmission line. In at least one example, magnitude of the localized voltage is represented by a staircase plot. Plot 600A shows the progressive frequency response of successive transmission line sections, where section 1 is closest to the signal source and section 50 is farthest. In the exemplary plot 600A, sections that are more proximal to the signal source (e.g., sections 1-10) may have the highest cut-off frequencies and may pass all frequencies ranging from DC to 50 MHZ. Beyond section 10, the cut-off frequencies of successive sections become progressively lower, restricting the passage of higher frequencies to the more proximal transmission line section. The more distal transmission line sections pass progressively lower frequencies. In this example, section 25 is preferentially excited with a 24.5 MHz signal which resulted in an approximately 1.5V in section 25. FIG. 6A indicates localized voltage produced in sections (cross-hatched) of the transmission line where frequencies propagate (voltage V is non-zero) and sections where frequencies do not propagate (voltage V is zero) Plot 600B in FIG. 6B shows an enlarged view of the voltage produced in section 25. FIG. 6C illustrates an example plot 600C showing a low frequency signal 602 and a high frequency signal 604 applied to transmission line 120. The x-axis represents time and the y-axis represents frequency of the applied signal. In this example, the frequency of high frequency signal 604 is varied periodically. Low frequency signal 602 is applied uniformly to transmission line 120 while high frequency signal 604 is used to preferentially excite selected sections of transmission line 120. In at least one example, low frequency signal 602 may be approximately 400 kHz and high frequency signal 604 may be varied (e.g., 24.5 MHz-100 MHZ).

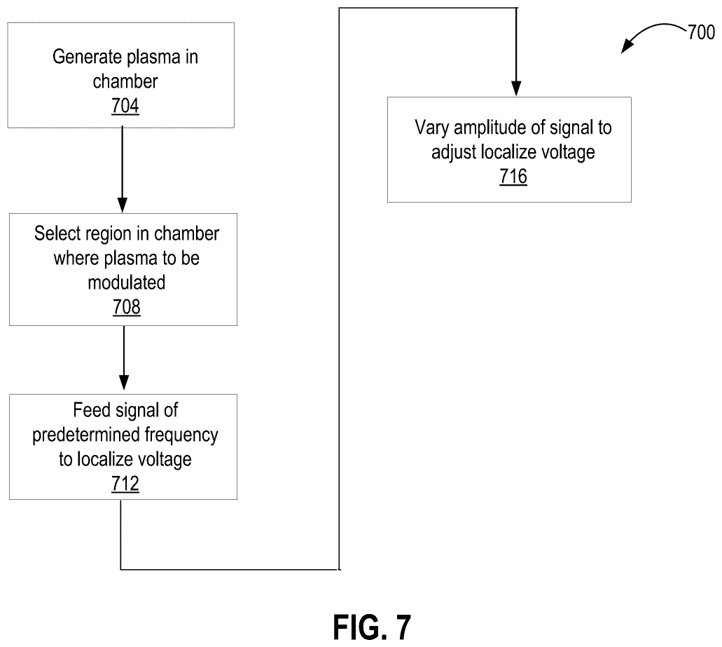

FIG. 7 is a flow diagram of method 700 of modulating a spatial distribution and an ion energy of a plasma in accordance with the disclosure. In at least one example, blocks here may be performed by software, hardware, and/or a combination of them. In block 704, plasma is generated in a plasma chamber (e.g., plasma chamber 104). In at least one example, plasma chamber includes a transmission line (e.g., transmission line 120) having a plurality of sections (e.g., S₁-S_{N}) each having one or more L-C filters (e.g., L₁, C₁). The L-C filters have respective cut-off frequencies.

In block 708, in at least one example, a region in the plasma chamber (e.g., plasma chamber 104) is selected. In at least one example, plasma is to be modulated in the selected region. In at least one example, method further comprises feeding an input signal of a predetermined frequency to transmission line 120 to localize resulting voltage at one or more of the plurality of sections adjacent to the selected part of the second region 106. In at least one example, in block 712, an input signal of a predetermined frequency is fed to the transmission line (e.g., transmission line 120) to localize resulting voltage at one or more of the sections (e.g., sections S₅-S₁₀) adjacent to the selected region of the plasma chamber. In at least one example, the predetermined frequency is less than or equal to cut-off frequencies of the one or more L-C filters of the selected sections. In block 716, in at least one example, amplitude of the input signal is varied to adjust the resulting localized voltage.

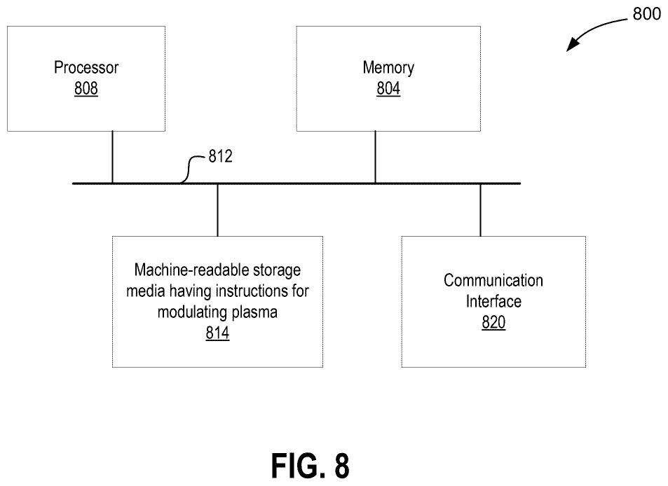

FIG. 8 illustrates system 800 comprising machine-readable storage media which includes instructions for modulating a spatial distribution and an ion energy of a plasma, in accordance with at least one example. System 800 includes memory 804, processor 808, network 812, machine-readable storage media 814, and communication interface 820.

In at least one example, memory 804 is a volatile or non-volatile memory. In at least one example, processor 808 is a Digital Signal Processor (DSP), an Application Specific Integrated Circuit (ASIC), a general-purpose Central Processing Unit (CPU), or a low power logic implementing a simple finite state machine to perform the method of modulating a spatial distribution and an ion energy of a plasma and/or various examples, etc.

In at least one example, machine-readable storage media 814 includes instructions for modulating a spatial distribution and an ion energy of a plasma. In at least one example, the instructions when executed cause processor 808 to perform a method comprising generating a plasma in a chamber including first and second regions. In at least one example, the first region includes a transmission line having a plurality of sections. In at least one example, an individual section of the plurality of sections includes one or more L-C filters. In at least one example, the second region contains the plasma. In at least one example, the instructions when executed cause processor 808 to perform a method comprising selecting a part of the section region where the plasma is to be modulated. In at least one example, the instructions when executed cause processor 808 to perform a method comprising feeding an input signal of a predetermined frequency to transmission line 120 to localize voltage at one or more sections of the plurality of sections, adjacent to the selected part of the second region.

In at least one example, the instructions when executed cause processor 808 to perform a method comprising varying an amplitude of the input signal to adjust the resulting voltage. In at least one example, the instructions when executed cause processor 808 to perform a method comprising varying a frequency of the input signal to switch the localized resulting voltage from the one or more sections of transmission line 120 to other one or more sections of transmission line 120. In at least one example, the predetermined frequency is less than or equal to cut-off frequencies of the one or more L-C filters of the one or more sections. Machine readable medium 814 has machine-readable instructions, that when executed, cause processor 808 to perform the method of modulating a spatial distribution and an ion energy of a plasma as discussed with reference to various examples.

Program software code/instructions associated with various examples may be implemented as part of an operating system or a specific application, component, program, object, module, routine, or other sequence of instructions or organization of sequences of instructions referred to as “program software code/instructions,” “operating system program software code/instructions,” “application program software code/instructions,” or simply “software” or firmware embedded in processor. In at least one example, the program software code/instructions associated with processes of various examples are executed by processor system 800.

In at least one example, program software code/instructions are stored in a computer executable storage medium 814 and executed by processor 808. Here, computer executable storage medium 814 may be a tangible machine-readable medium that can be used to store program software code/instructions and data that, when executed by a computing device, causes one or more processors (e.g., processor 808) to perform a process.

The tangible machine readable medium 814 may include storage of the executable software program code/instructions and data in various tangible locations, including for example ROM, volatile RAM, non-volatile memory and/or cache and/or other tangible memory as referenced in the present application. Portions of this program software code/instructions and/or data may be stored in any one of these storage and memory devices. In at least one example, program software code/instructions can be obtained from other storage, including, e.g., through centralized servers or peer to peer networks and the like, including the Internet. Different portions of the software program code/instructions and data can be obtained at different times and in different communication sessions or in the same communication session.

In at least one example, software program code/instructions can be obtained in their entirety prior to the execution of a respective software program or application. Alternatively, in at least one example, portions of the software program code/instructions and data can be obtained dynamically, e.g., just in time, when needed for execution. Alternatively, some combination of these ways of obtaining the software program code/instructions and data may occur, e.g., for different applications, components, programs, objects, modules, routines or other sequences of instructions or organization of sequences of instructions, by way of example. Thus, in at least one example, it may not be required that the data and instructions be on a tangible machine-readable medium in entirety at a particular instance of time.

Examples of tangible computer-readable media 814 include but are not limited to recordable and non-recordable type media such as volatile and non-volatile memory devices, read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs), etc.), among others. The software program code/instructions may be temporarily stored in digital tangible communication links while implementing electrical, optical, acoustical, or other forms of propagating signals, such as carrier waves, infrared signals, digital signals, etc. through such tangible communication links.

In at least one example, system 100 may be utilized in 3-D printing systems that include electrodes. In at least one example, system 100 may be used wherein high frequency signals are localized to selected sections of an electrode but low frequency signals are uniformly applied across the electrode.

Besides what is described herein, various modifications may be made to the disclosed examples and implementations thereof without departing from their scope. Therefore, illustrations of examples herein should be construed as examples only, and not restrictive to the scope of the present disclosure. The scope of the invention should be measured solely by reference to the claims that follow.

Following examples are provided that illustrate the various examples. The examples can be combined with other examples. As such, various examples can be combined with other examples without changing the scope of the invention. For example, example 7 can be combined with example 3 or 2, or both.

Example 1: A system comprising: a chamber including first and second regions, the chamber configured to produce and contain a plasma in the second region; a transmission line positioned in the first region, the transmission line including a plurality of sections, wherein an individual section of the plurality of sections includes one or more L-C filters, wherein the one or more L-C filters have respective cut-off frequencies, and wherein the transmission line includes a transmission line input; and a signal source electrically coupled to the transmission line input to feed an input signal to the transmission line input, wherein the one or more L-C filters pass low frequency components of the input signal but localize high frequency components of the input signal to selected sections of the transmission line.

Example 2: The system of example 1, wherein the first region is separated from the second region by a dielectric window.

Example 3: The system of example 1, wherein the low frequency components are passed by the one or more L-C filters to uniformly apply the low frequency components to the transmission line.

Example 4: The system of example 1, wherein the high frequency components are localized to the selected sections of the transmission line by selection of the respective cut-off frequencies of the one or more L-C filters.

Example 5: The system of example 1, wherein the selected sections in which the high frequency components are localized are switched by change in a frequency of the input signal fed to the transmission line.

Example 6: The system of example 1, wherein a voltage of the input signal is varied to vary a voltage of low frequency components uniformly applied to the transmission line.

Example 7: The system of example 1, wherein a voltage of the input signal is varied to vary a voltage at the selected sections in which the high frequency components are localized.

Example 8: The system of example 1, wherein a cut-off frequency of the one or more L-C filters decreases as it is positioned farther down the transmission line.

Example 9: The system of example 1, wherein the respective cut-off frequencies of the one or more L-C filters decrease as the input signal propagates down the transmission line.

Example 10: A system for modulating spatial distribution and ion energy of a plasma, the system comprising: a chamber including first and second regions separated by a separation window; a transmission line positioned in the first region, the transmission line including a plurality of sections, wherein an individual section of the plurality of sections includes one or more L-C filters which have respective cut-off frequencies, the transmission line having a transmission line input; and a signal source electrically coupled to the transmission line input to feed an input signal to the transmission line, wherein the one or more L-C filters pass low frequency components of the input signal but localize high frequency components of the input signal to selected sections of the transmission line, and wherein the spatial distribution and ion energy of the plasma in the second region is modulated in areas adjacent to the selected sections of the transmission line.

Example 11: The system of example 10, wherein the separation window comprises a dielectric.

Example 12: The system of example 10, wherein the spatial distribution of the plasma is modulated by variation of a voltage of the input signal.

Example 13: The system of example 10, wherein the selected sections in which the high frequency components are localized are switched by change in a frequency of the input signal.

Example 14: The system of example 10, wherein a voltage of the input signal is varied to vary a voltage of low frequency components on the transmission line.

Example 15: The system of example 10, wherein a voltage of the input signal is varied to vary a voltage across the selected sections in which the high frequency components are localized.

Example 16: A method of modulating a spatial distribution and an ion energy of a plasma, the method comprising: providing a chamber including first and second regions, wherein the first region includes a transmission line having a plurality of sections, wherein an individual section of the plurality of sections includes one or more L-C filters; generating the plasma in the second region; selecting a part of the second region where the plasma is to be modulated; feeding an input signal of a predetermined frequency to the transmission line to localize resulting voltage at one or more of the plurality of sections adjacent to the selected part of the second region; and varying an amplitude of the input signal to adjust the resulting voltage.

Example 17: The method of example 16, further comprising varying a frequency of the input signal to switch the localized resulting voltage from one or more sections of the transmission line to other one or more sections of the transmission line.

Example 18: The method of example 16, wherein the predetermined frequency is less than or equal to cut-off frequencies of the one or more L-C filters of the selected sections.

Example 19: A machine-readable storage media having machine executable instructions, that when executed, cause one or more machines to perform a method comprising: generating a plasma in a chamber including first and second regions, wherein the first region includes a transmission line having a plurality of sections, wherein an individual section of the plurality of sections includes one or more L-C filters, wherein the second region contains the plasma; selecting a part of the second region where the plasma is to be modulated; feeding an input signal of a predetermined frequency to the transmission line to localize resulting voltage at one or more sections, of the plurality of sections, adjacent to the selected part of the second region; and varying an amplitude of the input signal to adjust the resulting voltage.

Example 20: The machine-readable storage media of example 19, wherein the method further comprises varying a frequency of the input signal to switch the localized resulting voltage from the one or more sections of the transmission line to other one or more sections of the transmission line.

Example 21: The machine-readable storage media of example 19, wherein the predetermined frequency is less than or equal to cut-off frequencies of the one or more L-C filters of the one or more sections.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate example.

What is claimed is:

1. A system comprising:
a chamber including first and second regions, the chamber configured to produce and contain a plasma in the second region;
a transmission line positioned in the first region, the transmission line including a plurality of sections, wherein an individual section of the plurality of sections includes one or more L-C filters, wherein the one or more L-C filters have respective cut-off frequencies, and wherein the transmission line includes a transmission line input; and
a signal source electrically coupled to the transmission line input to feed an input signal to the transmission line input,
wherein the one or more L-C filters pass low frequency components of the input signal but localize high frequency components of the input signal to selected sections of the transmission line.

2. The system of claim 1, wherein the first region is separated from the second region by a dielectric window.

3. The system of claim 1, wherein the low frequency components are passed by the one or more L-C filters to uniformly apply the low frequency components to the transmission line.

4. The system of claim 1, wherein the high frequency components are localized to the selected sections of the transmission line by selection of the respective cut-off frequencies of the one or more L-C filters.

5. The system of claim 1, wherein the selected sections in which the high frequency components are localized are switched by change in a frequency of the input signal fed to the transmission line.

6. The system of claim 1, wherein a voltage of the input signal is varied to vary a voltage of low frequency components uniformly applied to the transmission line.

7. The system of claim 1, wherein a voltage of the input signal is varied to vary a voltage at the selected sections in which the high frequency components are localized.

8. The system of claim 1, wherein a cut-off frequency of the one or more L-C filters decreases as it is positioned farther down the transmission line.

9. The system of claim 1, wherein the respective cut-off frequencies of the one or more L-C filters decrease as the input signal propagates down the transmission line.

10. A system for modulating spatial distribution and ion energy of a plasma, the system comprising:
a chamber including first and second regions separated by a separation window;
a transmission line positioned in the first region, the transmission line including a plurality of sections, wherein an individual section of the plurality of sections includes one or more L-C filters which have respective cut-off frequencies, the transmission line having a transmission line input; and
a signal source electrically coupled to the transmission line input to feed an input signal to the transmission line,
wherein the one or more L-C filters pass low frequency components of the input signal but localize high frequency components of the input signal to selected sections of the transmission line, and
wherein the spatial distribution and ion energy of the plasma in the second region is modulated in areas adjacent to the selected sections of the transmission line.

11. The system of claim 10, wherein the separation window comprises a dielectric.

12. The system of claim 10, wherein the spatial distribution of the plasma is modulated by variation of a voltage of the input signal.

13. The system of claim 10, wherein the selected sections in which the high frequency components are localized are switched by change in a frequency of the input signal.

14. The system of claim 10, wherein a voltage of the input signal is varied to vary a voltage of low frequency components on the transmission line.

15. The system of claim 10, wherein a voltage of the input signal is varied to vary a voltage across the selected sections in which the high frequency components are localized.

16. A method of modulating a spatial distribution and an ion energy of a plasma, the method comprising:
providing a chamber including first and second regions, wherein the first region includes a transmission line having a plurality of sections, wherein an individual section of the plurality of sections includes one or more L-C filters;
generating the plasma in the second region;
selecting a part of the second region where the plasma is to be modulated;
feeding an input signal of a predetermined frequency to the transmission line to localize resulting voltage at one or more of the plurality of sections adjacent to the selected part of the second region; and
varying an amplitude of the input signal to adjust the resulting voltage.

17. The method of claim 16, further comprising varying a frequency of the input signal to switch the localized resulting voltage from one or more sections of the transmission line to other one or more sections of the transmission line.

18. The method of claim 16, wherein the predetermined frequency is less than or equal to cut-off frequencies of the one or more L-C filters of the selected sections.

19. A machine-readable storage media having machine executable instructions, that when executed, cause one or more machines to perform a method comprising:
generating a plasma in a chamber including first and second regions, wherein the first region includes a transmission line having a plurality of sections, wherein an individual section of the plurality of sections includes one or more L-C filters, wherein the second region contains the plasma;
selecting a part of the second region where the plasma is to be modulated;
feeding an input signal of a predetermined frequency to the transmission line to localize resulting voltage at one or more sections, of the plurality of sections, adjacent to the selected part of the second region; and
varying an amplitude of the input signal to adjust the resulting voltage.

20. The machine-readable storage media of claim 19, wherein the method further comprises varying a frequency of the input signal to switch the localized resulting voltage from the one or more sections of the transmission line to other one or more sections of the transmission line.

21. The machine-readable storage media of claim 19, wherein the predetermined frequency is less than or equal to cut-off frequencies of the one or more L-C filters of the one or more sections.
